(19) United States
(12) Patent Application Publication
(10) Pub. No.: US 2024/0186268 A1
(43) Pub. Date: Jun. 6, 2024

(54) DIRECTLY BONDED STRUCTURE WITH FRAME STRUCTURE

(71) Applicant: ADEIA SEMICONDUCTOR BONDING TECHNOLOGIES INC., San Jose, CA (US)

(72) Inventors: Cyprian Emeka Uzoh, San Jose, CA (US); Rajesh Katkar, Milpitas, CA (US)

(21) Appl. No.: 18/523,702

(22) Filed: Nov. 29, 2023

Related U.S. Application Data
(60) Provisional application No. 63/429,478, filed on Dec. 1, 2022.

(51) Int. Cl. H01L 23/00; H01L 23/053; H01L 23/31

(52) U.S. Cl. CPC H01L 23/562; H01L 23/053; H01L 23/3157; H01L 24/08; H01L 2224/08225

(57) ABSTRACT

A bonded structure is disclosed. The bonded structure can include a carrier including a surface having a first region and a second region, an integrated device die directly bonded to the first region of the carrier, and a frame structure that is disposed on the second region. The frame structure can be a continuous frame structure. The frame structure can have a first elongate frame element and a second elongate frame element that are positioned between the integrated device die and the second section. At least a portion of the second region between the first frame element and the second frame element can be free from the frame structure.

### CROSS-REFERENCE TO RELATED APPLICATIONS

This application claims priority to U.S. Provisional Patent Application No. 63/429,478, filed Dec. 1, 2022, the entire contents of which are incorporated by reference herein in their entirety and for all purposes.

### BACKGROUND

### Field

The field relates to bonded structures and methods of forming a direct hybrid bonded structure with a frame structure.

### Description of the Related Art

Microelectronic elements, such as integrated device dies or chips, may be mounted or stacked on other elements thereby forming a bonded structure. Hybrid bonding involves directly bonding non-conductive features (e.g., inorganic dielectrics) of different elements together, without intervening adhesives, while also directly bonding conductive features (e.g., metal pads or lines) of the elements together. For example, a microelectronic element can be mounted to a carrier, such as an interposer, a reconstituted wafer or element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. There is a continuing need for improved methods for forming the bonded structure.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to direct hybrid bonding.

FIG. 1B is a schematic cross-sectional side view of the two elements shown in FIG. 1A after direct hybrid bonding.

FIG. 2A is a schematic top plan view of a bonded structure.

FIG. 2B is a schematic side view of the bonded structure on a substrate.

FIG. 3A is a schematic top plan view of a bonded structure.

FIG. 3B is a schematic side view of the bonded structure.

FIG. 4A is a schematic top plan view of a bonded structure according to an embodiment.

FIG. 4B is a schematic side view of the bonded structure of FIG. 4A.

FIG. 5A is a schematic top plan view of a bonded structure according to another embodiment.

FIG. 5B is a schematic side view of the bonded structure of FIG. 5A.

FIGS. 6A to 7H are schematic top plan views of bonded structures according to various embodiments.

FIG. 8 shows a schematic top plan view of a plurality of frame structures formed in or with a frame substrate (e.g., a wafer).

FIGS. 9A-9F show a method of forming a bonded structure according to an embodiment.

FIGS. 10A-10H show a method of forming a bonded structure according to another embodiment.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

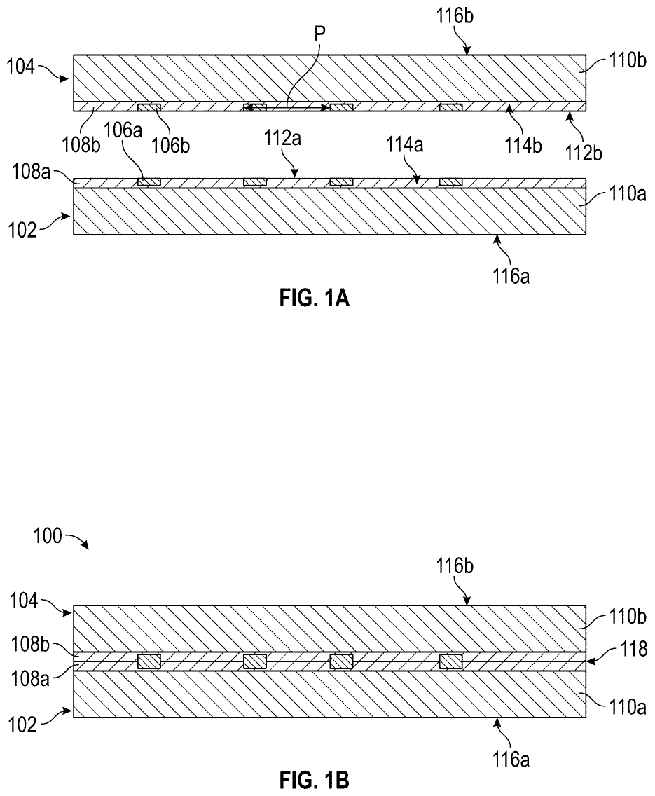

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As described above, the non-conductive bonding layers 108a, 108b can be directly bonded to one another without an adhesive and, subsequently, the bonded structure 100 can be annealed. Upon annealing, the conductive features 106a, 106b can expand and contact one another to form a metal-to-metal direct bond. In some embodiments, the materials of the conductive features 106a, 106b can interdiffuse during the annealing process.

When one or more elements are bonded to a host element that has a greater footprint, the host element may be warped due to uneven stress on a surface of the host element caused by uneven distribution of the one or more elements on the surface of the host element. The uneven stress may eventually create failures during assembly process or device operation like stress fractures, microcracks, etc. In some embodiments, the one or more elements can different sizes. In some embodiments, there may be thermal distribution challenges in a stacked structure that includes chiplets over, for example, a high performance processors.

Various embodiments disclosed herein relate to bonded structures with frame structure that prevents or reduces formation of host element warpage. In some embodiments, the frame structure can enable a balanced distribution of mass, size, and/or coefficient of thermal expansion (CTE) over the surface of the host element.

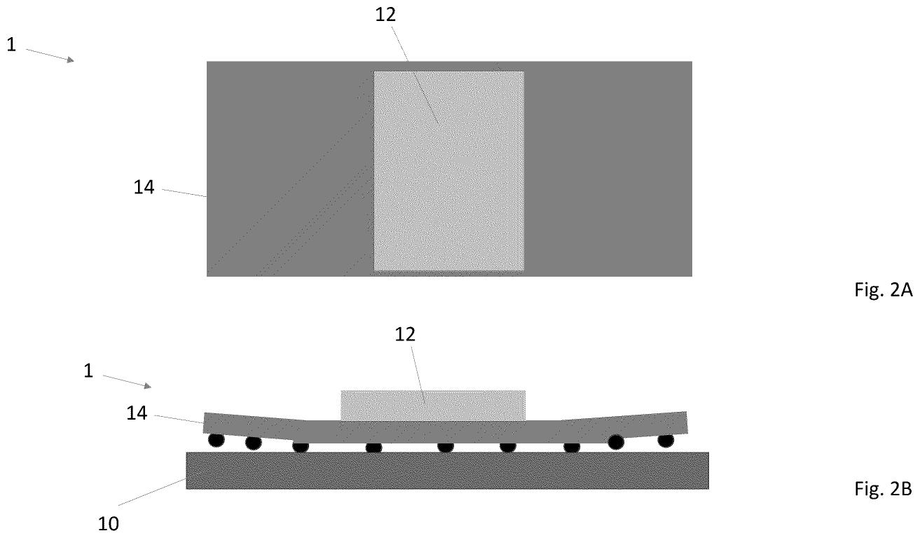

FIG. 2A is a schematic top plan view of a bonded structure 1. FIG. 2B is a schematic side view of the bonded structure 1 on a substrate 10. The bonded structure 1 includes an integrated device die 12 (e.g., an active die) mounted on a carrier 14 (e.g., another integrated device die, an interposer, a reconstituted element, etc.). The integrated device die 12 has a footprint that is smaller than a footprint of the carrier 14. In some embodiments, the portion of carrier 14 not occupied by an integrated devices die 12 may be filled with an insulating materials with a CTE different from the carrier 14 or the integrated device die 12 (e.g. an inorganic material like silicon oxide, silicon nitride, etc. or an organic material like resin, epoxy, etc.) The uneven distribution of elements bonded to or deposited over the surface of the carrier 14 creates uneven stress causing warpage. The warped carrier 14 can lead to defects in a system including manufacturing or operational failures. For example, the carrier 14 may be warped such that one or more electrical connections between the carrier 14 and the substrate 10 is/are disconnected or there forms a delamination at the bond interface between the carrier 12 and the integrated device die 12 and/or the deposited encapsulation. Such defects can contribute to yield loss and loss of structural integrity.

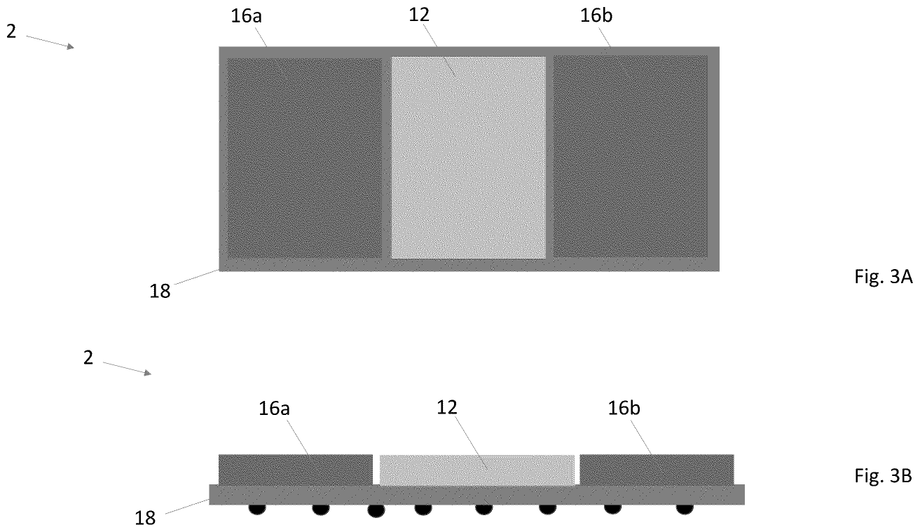

FIG. 3A is a schematic top plan view of a bonded structure 2. FIG. 3B is a schematic side view of the bonded structure 2. The bonded structure 2 includes an integrated device die 12 (e.g., an active die) and dummy dies 16a, 16b mounted on a carrier 18 (e.g., an interposer, another device die, a reconstituted element, etc.). The dummy dies 16a, 16b can provide structural support to the carrier 18 and contribute to prevent or mitigate carrier warpage and generates a comparatively more uniform stress distribution at the interface or surface of the carrier.

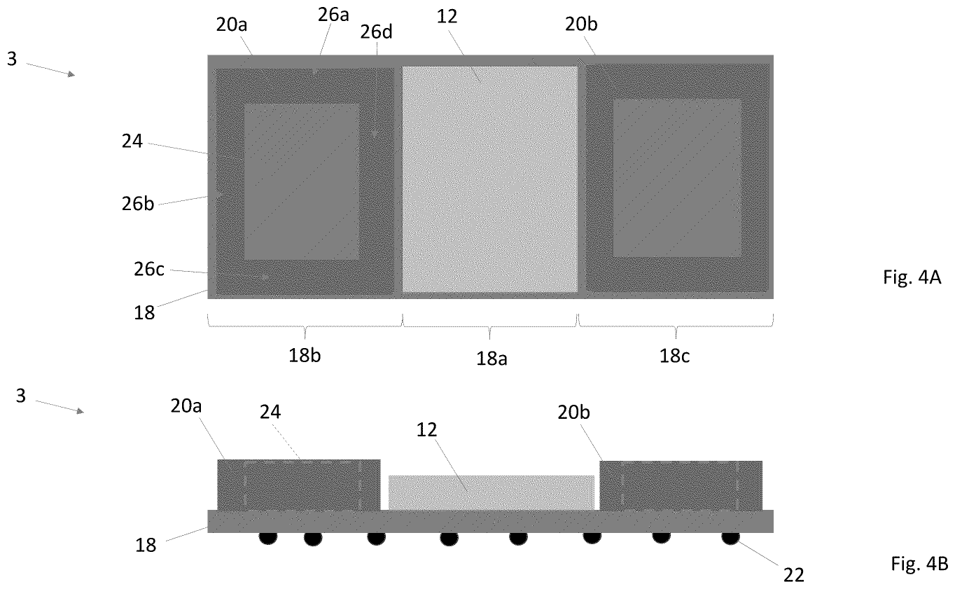

FIG. 4A is a schematic top plan view of a bonded structure 3 according to an embodiment. FIG. 4B is a schematic side view of the bonded structure 3. The bonded structure 3 includes an integrated device die 12 (e.g., an active die) and frame structures 20a, 20b mounted on a carrier 18 (e.g., an interposer, another device die, a reconstituted element, etc.).

The integrated device die 12 can comprise active circuitry (e.g., at least one transistor). For example, the integrated device die 12 can comprise a processor die, a memory die, a sensor die, a microelectromechanical systems (MEMS) die, or any other suitable device that includes active circuitry (such as transistors or other active devices). One integrated device die 12 is shown in FIGS. 4A and 4B, but it should be appreciated that any suitable number of device dies can be provided in the bonded structure 3. For example, two or three integrated device dies can be mounted to the carrier 18, or more than three integrated device dies can be mounted to the carrier. In some embodiments, an integrated device die 12 can be a die stack (i.e. a stack two or more dies is mounted to the carrier)

The carrier 18 can comprise any suitable support structure for the integrated device die 12. For example, in some embodiments, the carrier 18 can comprise an interposer (such as a semiconductor interposer), a semiconductor or dielectric (e.g., glass) substrate, another integrated device die (e.g., an active chip with active electronic circuitry), a reconstituted wafer or element, etc. For example, the carrier 18 can comprise a processor die and/or a memory die. In some embodiments, the carrier 18 can be configured to be connected to a substrate or a larger system by way of, for example, conductive bumps 22 (e.g., solder balls). The carrier 18 can comprise a material (e.g., a semiconductor material, a dielectric material, etc.) having a first CTE. In various embodiments, the integrated device die 12 can have a CTE that is substantially similar to the first CTE of the carrier 18. In some embodiments, bulk material of one or more of the die 12 may be the same material as corresponding bulk material of the carrier 18. In some embodiments, the integrated device die 12 and the carrier 18 can have the same substrate bulk material (e,g, Si), but with different thicknesses (e.g. 100 um thick carrier 18 and 5 um thick device die), which can effectively create a large CTE differential between the carrier 18 and the device die 12. The large CTE differential may be created even with similar thicknesses of the dielectric and metallization layers on top of the carrier 18 and the die 12 (e.g. back end of line (BEOL) layers) depending on individual layer thicknesses of BEOL stack, which typically comprises aluminum and/or copper metal lines and inorganic dielectrics (e.g. oxide and nitrides), which can increase or decrease the effective CTE of the die or carrier depending on the BEOL layer thicknesses. In various embodiments, the carrier 18 can comprise silicon, glass, or any other suitable material. In some embodiments, the carrier 18 can comprise an integrated device die (such as a processor die) that has a larger lateral footprint than the die 12. In some embodiments, the die 12 and the carrier 18 can have a significantly different coefficients of thermal expansion (CTEs), as disclosed herein, defining a heterogenous structure.

The integrated device die 12 can be mounted to a first region 18a the carrier 18 in any suitable manner. For example, the die 12 can be directly hybrid bonded to the carrier 18 without an intervening adhesive, as explained herein. In such embodiments, nonconductive field regions of the die 12 can be directly bonded to corresponding nonconductive field regions of the carrier 18 without an adhesive. Moreover, conductive contacts of the die 12 can be directly bonded to corresponding conductive contacts of the carrier 18 without an adhesive. In other embodiments, however, the die 12 can be mounted to the carrier 18 with an adhesive.

The frame structures 20a, 20b can be mounted to respective second and third regions 18b, 18c the carrier 18 in any suitable manner. For example, the frame structures 20a, 20b can be directly bonded to the carrier 18 without an intervening adhesive, as explained herein. The frame structures 20a, 20b can contribute to preventing or mitigating the carrier 18 from being deformed or warped. In some embodiments, the frame structures 20a, 20b can provide mechanical support for the carrier 18, and/or reduce the effects of CTE mismatch between the die 12 and the carrier 18. In various embodiments, the frame structures 20a, 20b include no active circuitry therein. In some embodiments, at least 80%, at least 90%, or at least 95% of the front and back surfaces of the frame structure 20a, 20b is devoid of circuitry. The frame structures 20a, 20b can comprise a semiconductor material (e.g., silicon), an insulating material (e.g., glass), or any other suitable material type that has a CTE that substantially matches (or is close to) the CTE of the carrier 18 and/or the die 12. In some embodiments, the frame structures 20a, 20b can comprise the same material as the carrier 18 and/or the die 12. In other embodiments, the frame structures 20a, 20b can comprise a material that is different from that of the carrier 18 and/or the die 12. Each frame structure 20a, 20b can comprise the same material. In various embodiments, the CTE of the frame structures 20a, 20b can be within 10%, within 5%, or within 1% of the CTE of the carrier 18 and/or of the integrated device die 12. In various embodiments, the CTE of the frame structures 20a, 20b can be less than 10 ppm/° C., less than 8 ppm/° C., or less than 7 ppm/° C. For example, the CTE of the frame structures 20a, 20b can be in a range of 3 ppm to 10 ppm/° C., or in a range of 3 ppm/° C. to 7 ppm/° C.

Beneficially, the frame structures 20a, 20b can reduce the stresses imparted to the carrier 18 and/or the die 12, since the material composition of the frame structures 20a, 20b is selected to have a CTE that substantially matches that of the carrier 18 and/or the die 12. In some embodiments, the frame structures 20a, 20b can be mounted so as to cover 20% or more of an unoccupied area of the carrier 18 (e.g., the second and third regions 18b, 18c of the carrier 18 that do not support the die 12). For example, the frame structures 20a, 20b can be mounted so as to cover at least 20%, at least 30%, at least 40%, at least 50%, or at least 75% of the unoccupied area of the carrier 18. In some embodiments, the frame structures 20a, 20b can be mounted so as to cover a range of 20% to 75% of the unoccupied area of the carrier 18, a range of 30% to 75% of the unoccupied area of the carrier 18, or a range of 50% to 75% of the unoccupied area of the carrier 18.

As shown in FIGS. 4A and 4B, in some embodiments, the frame structures 20a, 20b can have a continuous annular shape. In some embodiments, the continuous annular shape of each of the frame structures 20a, 20b can have a unitary structure, a monolithic piece, a seamless structure without joints or connectors. For example, the frame structures 20a, 20b can be formed from a material removal process, such as an etching process. In some embodiments, the frame structures 20a, 20b can be shaped so as to include an opening 24 over interior portions of the second and third regions 18b, 18c. Although FIG. 4A indicates the shape of the opening 24 to be rectangular, the shape can also be square, oval, circular or any other regular or irregular shape. In some embodiments, the openings 24 in frames 20a and 20b may be similar in shape and size, or they may be different in shape and/or size in some other embodiments. The frame structures 20a, 20b can have sections. The frame structure 20a can have a plurality of elongate sections angled relative to one another, including, e.g., first to fourth elongate sections 26a-26d. The first section 26a of the frame structure 20a can extend in a first direction, the second section 26b of the frame structure 20a can extend in a second direction angled relative to the first direction, the third section 26c of the frame structure 20a can extend in a third direction angled relative to the second direction, and the fourth section 26d of the frame structure 20a can extend in a fourth direction angled relative to the third direction. At least a portion of the second region 18b of the carrier 18 between the first section 26a and the third section 26c can be free from, devoid of, or does not include the frame structure 20a. The frame structure 20a can be omitted from at least a portion of the second region 18b of the carrier 18 between the first section 26a and the third section 26c. At least a portion of the second region 18b of the carrier 18 between the second section 26b and the fourth section 26d (or the integrated device die 12) can be free from or does not include the frame structure 20a. The frame structure 20a can be omitted from at least a portion of the second region 18b of the carrier 18 between the first section 26a and the fourth section 26d. The first section 26a, the second section 26b, and the third section 26c can extend along edge regions of the carrier 18. A thickness of the frame structures 20a, 20b can be equal to, thicker than, or thinner than a thickness of the integrated device die 12.

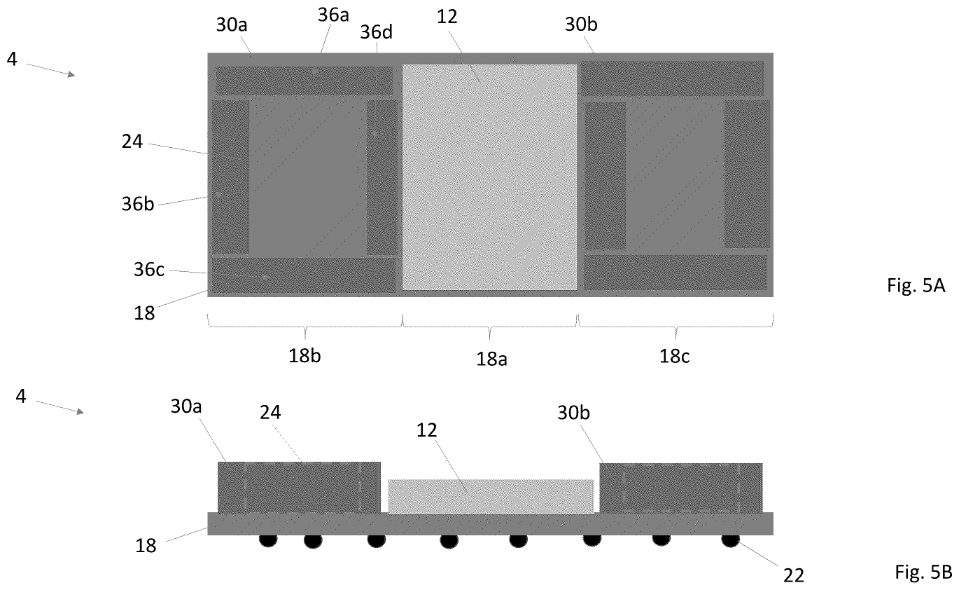

FIG. 5A is a schematic top plan view of a bonded structure 4 according to an embodiment. FIG. 5B is a schematic side view of the bonded structure 4. Unless otherwise noted, the components of FIGS. 5A and 5B may be the same as or generally similar to like components of other figures disclosed herein. The bonded structure 4 includes an integrated device die 12 (e.g., an active die) and frame structures 30a, 30b mounted on a carrier 18 (e.g., an interposer). The bonded structure 4 can be generally similar to the bonded structure 5 of FIGS. 4A and 4B except that, unlike the frame structures 20a, 20b, the frame structures 30a, 30b have discontinuous frame elements (the first to forth frame elements 36a, 36b, 36c, 36d).

The frame structures 30a, 30b can be mounted to respective second and third regions 18b, 18c the carrier 18 in any suitable manner. For example, the frame structures 30a, 30b can be directly bonded to the carrier 18 without an intervening adhesive, as explained herein. The frame structures 30a, 30b can contribute to preventing or mitigating the carrier 18 from being deformed or warped. In some embodiments, the frame structures 30a, 30b can provide mechanical support for the carrier 18, and/or reduce the effects of CTE mismatch between the die 12 and the carrier 18. In various embodiments, the frame structures 30a, 30b include no active circuitry therein. The frame structures 30a, 30b can comprise a semiconductor material (e.g., silicon), an insulating material (e.g., glass), or any other suitable material type that has a CTE that substantially matches (or is close to) the CTE of the carrier 18 and/or the die 12. In some embodiments, the frame structures 30a, 30b can comprise the same material as the carrier 18 and/or the die 12. In other embodiments, the frame structures 30a, 30b can comprise a material that is different from that of the carrier 18 and/or the die 12. Each frame structure 30a, 30b can comprise the same material. In various embodiments, the CTE of the frame structures 30a, 30b can be within 10%, within 5%, or within 1% of the CTE of the carrier 18 and/or of the integrated device die 12. In various embodiments, the CTE of the frame structures 30a, 30b can be less than 10 ppm/° C., less than 8 ppm/° C., or less than 7 ppm/° C. For example, the CTE of the frame structures 30a, 30b can be in a range of 1 ppm/° C. to 10 ppm/° C., or 3 ppm/° C. to 7 ppm/° C.

Beneficially, the frame structures 30a, 30b can reduce the stresses imparted to the carrier 18 and/or the die 12, since the material composition of the frame structures 30a, 30b is selected to have a CTE that substantially matches that of the carrier 18 and/or the die 12. In some embodiments, the frame structures 30a, 30b can be mounted so as to cover 20% or more of an unoccupied area of the carrier 18 (e.g., the second and third regions 18b, 18c of the carrier 18 that do not support the die 12). For example, the frame structures 30a, 30b can be mounted so as to cover at least 20%, at least 30%, at least 40%, at least 50%, or at least 75% of the unoccupied area of the carrier 18. In some embodiments, the frame structures 30a, 30b can be mounted so as to cover a range of 20% to 75% of the unoccupied area of the carrier 18, a range of 30% to 75% of the unoccupied area of the carrier 18, or a range of 50% to 75% of the unoccupied area of the carrier 18.

As shown in FIGS. 5A and 5B, in some embodiments, the frame structures 30a, 30b can have a generally annular shape. For example, the frame structures 30a, 30b can be shaped so as to include an opening 24 over interior portions of the second and third regions 18b, 18c. The first frame element 36a of the frame structure 30a can extend in a first direction, the second frame element 36b of the frame structure 30a can extend in a second direction angled relative to the first direction, the third frame element 36c of the frame structure 30a can extend in a third direction angled relative to the second direction, and the fourth frame element 36d of the frame structure 30a can extend in a fourth direction angled relative to the third direction. At least a portion of the second region 18b of the carrier 18 between the first frame element 36a and the third frame element 36c can be free from the frame structure 30a. At least a portion of the second region 18b of the carrier 18 between the second frame element 36b and the fourth frame element 36d (or the integrated device die 12) can be free from the frame structure 30a. The first frame element 36a, the second frame element 36b, and the third frame element 36c can extend along edge regions of the carrier 18. A thickness of the frame structures 30a, 30b can be equal to, thicker than, or thinner than a thickness of the integrated device die 12.

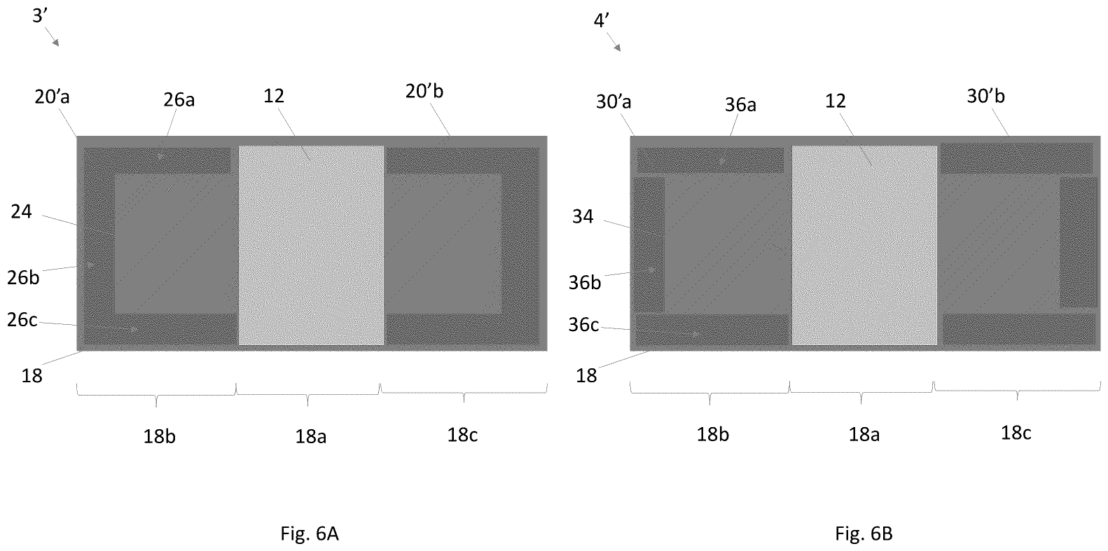

FIG. 6A is a schematic top plan view of a bonded structure 3′ according to an embodiment. The bonded structure 3′ is generally similar to the bonded structure 3 of FIGS. 4A and 4B. Unlike the frame structures 20a, 20b shown in FIGS. 4A and 4B, the frame structures 20′a, 20′b do not include the fourth section 26d that is present in the frame structures 20a, 20b. Rather, in FIG. 6A, the frame structures form a C-shape facing the die 12. In such arrangements, the die 12 can effectively serve as a fourth section of the frame to support the carrier 18.

FIG. 6B is a schematic top plan view of a bonded structure 4′ according to an embodiment. The bonded structure 4′ is generally similar to the bonded structure 4 of FIGS. 5A and 5B. Unlike the frame structures 30a, 30b shown in FIGS. 5A and 5B, the frame structures 30′a, 30′b do not include the fourth frame element 36d that is present in the frame structures 30a, 30b.

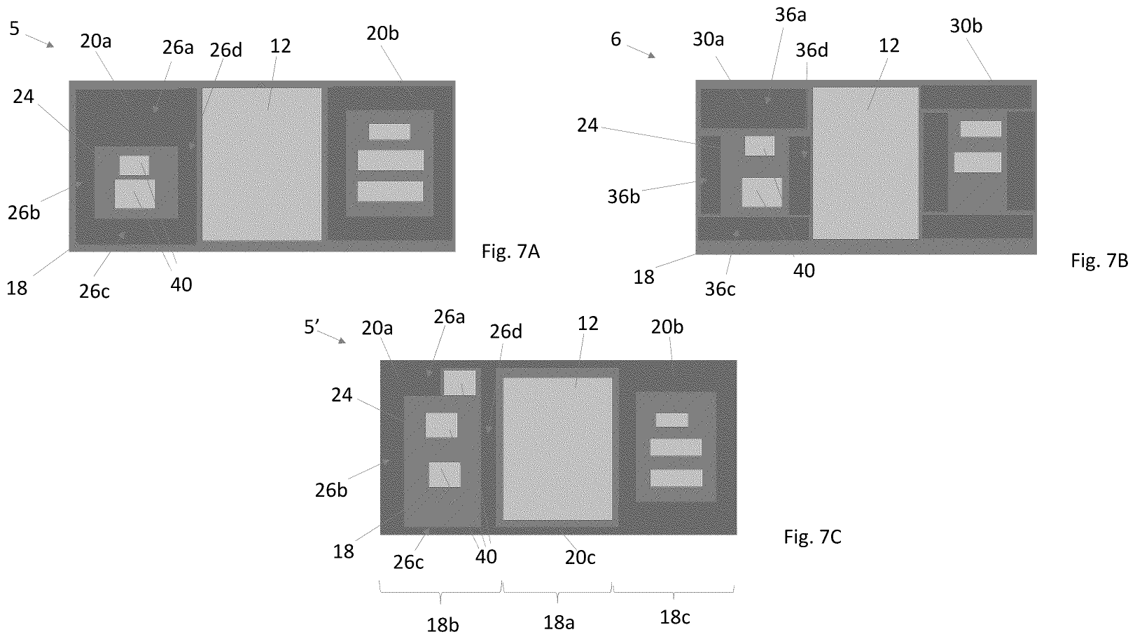

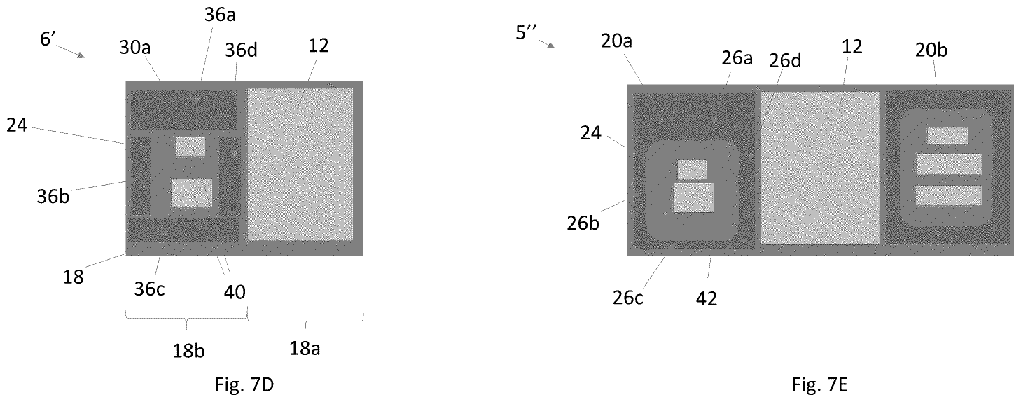

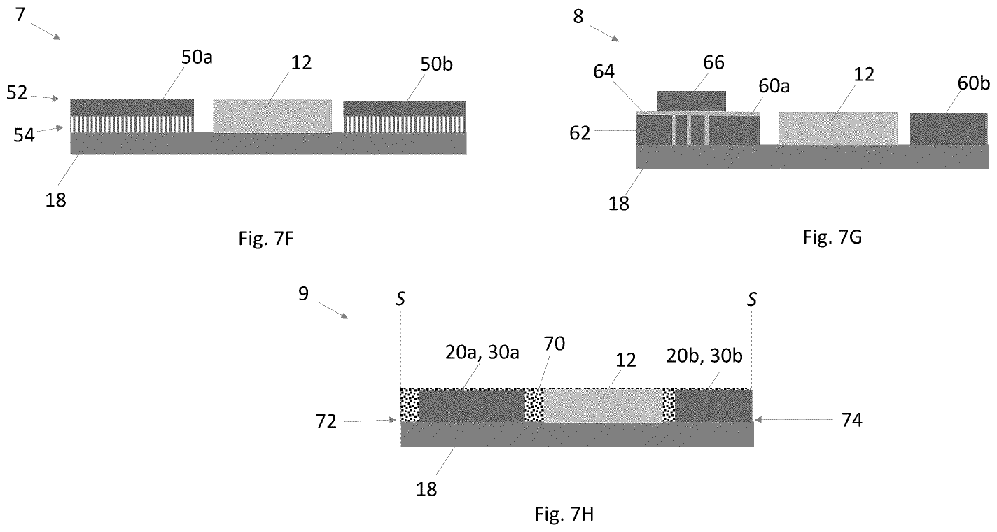

The opening 24 of the frame structures disclosed herein can enable additional electronic components to be mounted to the carrier 18 as shown in, for example, FIGS. 7A-7C. In some embodiments, the shape of a frame structure can be determined based at least in part on the location(s) and the size(s) the additional electronic components mounted on the carrier 18.

FIG. 7A is a schematic top plan view of a bonded structure 5 according to an embodiment. The bonded structure 5 includes an integrated device die 12 (e.g., an active die), frame structures 20a, 20b, and electronic components 40 mounted on a carrier 18 (e.g., an interposer). The electronic components 40 can comprise active circuitry and/or passive circuitry. For example, the electronic components 40 can comprise a processor die, a memory die, a sensor die, a microelectromechanical systems (MEMS) die, or any other suitable device that includes active circuitry (such as transistors or other active devices). In some embodiments, the components 40 can comprise passive elements, such as resistors, capacitors, inductors, etc. Two electronic components 40 are shown in the opening 24 of the frame structure 20a and three electronic components 40 are shown in the opening 24 of the frame structure 20b, but it should be appreciated that any suitable number of electronic components can be provided in the bonded structure 5. In some embodiments, the electronic components 40 can be smaller than the integrated device die 12. In some embodiments, one or more of electronic components 40 can be a stack of 2 or more die.

In some embodiments, widths and/or lengths of the first to fourth sections 26a-26d can vary. For example, the first section 26a can be wider than the second section 26b, the third section 26c, and/or the fourth section 26d.

FIG. 7B is a schematic top plan view of a bonded structure 6 according to an embodiment. Unless otherwise noted, the components of FIG. 7B may be the same as or generally similar to like components of other figures disclosed herein. The bonded structure 6 includes an integrated device die 12 (e.g., an active die), frame structures 30a, 30b, and electronic components 40 mounted on a carrier 18 (e.g., an interposer). The electronic components 40 can comprise active circuitry. In some embodiments, widths and/or lengths of the first to fourth frame elements 36a-36d can vary. For example, the first frame element 36a can be wider than the second frame element 36b, the third frame element 36c, and/or the fourth frame element 36d.

FIG. 7C is a schematic top plan view of a bonded structure 5′ according to an embodiment. Unless otherwise noted, the components of FIG. 7C may be the same as or generally similar to like components of other figures disclosed herein. The bonded structure 5′ includes an integrated device die 12 (e.g., an active die), frame structures 20a, 20b, 20c and electronic components 40 mounted on a carrier 18 (e.g., an interposer).

As illustrated in FIG. 7C, the first section 26a of the frame structure 20a can have varying widths. The fame structure 20c can be provided in a first region 18a of the carrier 18. The frame structure 20c can be provided between the frame structures 20a, 20b. In the illustrated embodiment, the frame structures 20a, 20b, 20c are formed continuously. However, a skilled artisan will understand that a plurality of disconnected frame elements can define the frame structures 20a, 20b, 20c in some other embodiments.

FIG. 7D is a schematic top plan view of a bonded structure 6′ according to an embodiment. Unless otherwise noted, the components of FIG. 7D may be the same as or generally similar to like components of other figures disclosed herein. The bonded structure 6′ includes an integrated device die 12 (e.g., an active die), frame structure 30a and electronic components 40 mounted on a carrier 18 (e.g., an interposer). The integrated device die 12 can be bonded to the first region 18a of the carrier 18, and the frame structure 30a can be bonded to the second region 18b of the carrier 18.

FIG. 7E is a schematic top plan view of a bonded structure 5″ according to an embodiment. Unless otherwise noted, the components of FIG. 7E may be the same as or generally similar to like components of other figures disclosed herein. The bonded structure 5″ includes an integrated device die 12 (e.g., an active die), frame structures 20a, 20b and electronic components 40 mounted on a carrier 18 (e.g., an interposer). The frame structures 20a, 20b can have one or more rounded inner edges 42. In some embodiments, the frame structures 20a, 20b can have one or more rounded outer edges 42a (as seen from a top plan view). In some other embodiments, the opening 24 can comprise a circular or oval shape.

FIG. 7F is a schematic side view of a bonded structure 7 according to an embodiment. Unless otherwise noted, the components of FIG. 7F may be the same as or generally similar to like components of other figures disclosed herein. The bonded structure 7 includes an integrated device die 12 (e.g., an active die) and frame structures 50a, 50b mounted on a carrier 18 (e.g., an interposer). In some embodiments, the frame structure 50a, 50b can have a plurality of sections, such as the first to forth sections 26a-26d of the frame structures 20a, 20b, and/or a plurality of frame elements, such as the first to fourth frame elements 36a-36d of the frame structures 30a, 30b.

The frame structures 50a, 50b can include a dummy portion 52 and a device portion 54. The dummy portion 52 can make up a majority of the frame structures 50, 50b. In some embodiments, the device portion 54 can comprise an active device or a passive device. The frame structures 50a, 50b can be bonded to the carrier 18 in any suitable manner. For example, the frame structures 50a, 50b can be directly bonded to the carrier 18 without an intervening adhesive, as described herein. The frame structures 50a, 50b may include a nonconductive field region and a conductive feature that are directly bonded to a corresponding nonconductive field region and a corresponding conductive feature of the carrier 18.

FIG. 7G is a schematic side view of a bonded structure 8 according to an embodiment. Unless otherwise noted, the components of FIG. 7G may be the same as or generally similar to like components of other figures disclosed herein. The bonded structure 8 includes an integrated device die 12 (e.g., an active die) and frame structures 60a, 60b mounted on a carrier 18 (e.g., an interposer). In some embodiments, the frame structure 60a, 60b can have a plurality of sections, such as the first to fourth sections 26a-26d of the frame structures 20a, 20b, and/or a plurality of frame elements, such as the first to fourth frame elements 36a-36d of the frame structures 30a, 30b.

The frame structure 60a can include one or more vias 62. The vias 62 can extend through a thickness of the frame structure 60a from a first side to a second side. The frame structure 60a can include a redistribution layer (RDL) 64 on top and/or bottom of frame structure 60a. The vias 62 can be coupled to the RDL 64. The vias 62 can provide electrical connections between the carrier 18 and the RDL 64. In some embodiments, a nonconductive field region of the frame structure 60a can be directly bonded to a corresponding nonconductive field region of the carrier and the vias 62 can be directly bonded to corresponding conductive features of the carrier 18.

In some embodiments, an element 66 can be stacked over the frame structure 60a. The element 66 may be an dummy element that does not include electrical circuitry, or an active element that includes electrical circuitry. In some embodiments, the vias 62 and the RDL 64 can at least partially provide an electrical path between the carrier 18 and the element 66. In some embodiments, the element 66 can be directly bonded to the frame structure 60a in any suitable manner disclosed herein.

FIG. 7H is a schematic side view of a bonded structure 9 according to an embodiment. Unless otherwise noted, the components of FIG. 7H may be the same as or generally similar to like components of other figures disclosed herein. The bonded structure 9 includes an integrated device die 12 (e.g., an active die) and frame structures 20a, 20b or 30a, 30b mounted on a carrier 18 (e.g., an interposer).

As shown in FIG. 7H, a protective material 70 can be provided over the carrier 18. The integrated device dies 12 can be at least partially embedded (e.g., completely embedded or buried) within the protective material 70. In some embodiments, the protective material 70 can cover the upper surfaces of the dies 12 (e.g., can be fully embedded). In other embodiments, the upper surfaces of the dies 12 can be exposed through the protective material 70. In some embodiments, the protective material 70 can comprise an organic material such as a resin, an epoxy, a molding compound or a polymer material (e.g., polyimide or potting compound), or an inorganic material such as silicon oxide, silicon nitride, etc. In some embodiments, the protective material 70 can have a CTE that is different from the CTE of the carrier 18 (and/or of the dies 12). For example, the CTE of the protective material 70 can differ from the first CTE of the carrier 18 (and/or of the dies 12) by an amount that is sufficiently large so as cause CTE-induced stresses on the carrier 18 and/or dies 12. During process steps at elevated temperatures, the CTE mismatch between the protective material 70 and the carrier 18 (and/or dies 12) can induce stresses that cause warpage, cracks, or other types of damage to the components of the package. In some embodiments, the frame structures 20a, 20b or 30a, 30b can reduce the effects of CTE mismatch between the protective material 70 and the carrier 18 (and/or dies 12).

The bonded structure 9 can be formed from a singulation process by which a larger wafer or reconstituted wafer is singulated along singulation streets S to yield a plurality of singulated packages. In some embodiments, singulation can comprise a sawing process, an etching process, or any other suitable process by which packages 9 can be formed from a larger wafer or reconstituted wafer. After singulation, the outer side edges can comprise singulation markings indicative of the singulation process. For example, for saw singulation processes, the singulation markings can comprise saw markings, such as striations in the singulated surface. For etch singulation processes, the singulation markings can comprise marks or microstructures indicative of the etch pathway. The outer side edge 72 can include an edge of the carrier 18 and the protective material 70, each of which may include markings indicative of the singulation process. The outer side edge 74 can include an outer edge of the frame structure 20b, 30b and an edge of the carrier 18 (and the protective material 70 when the protective material 70 has a thickness that is greater than a thickness of the frame structure 20b, 30b), each of which may include markings indicative of the singulation process. In various embodiments, the singulation streets S can pass through one or more of the frame structures 20a, 30a, 20b, 30b such that, upon singulation, the protective material 70 and one or more frame structures 20a, 30a, 20b, 30b can be exposed along one or more outer side edges 72, 74 of the package 9.

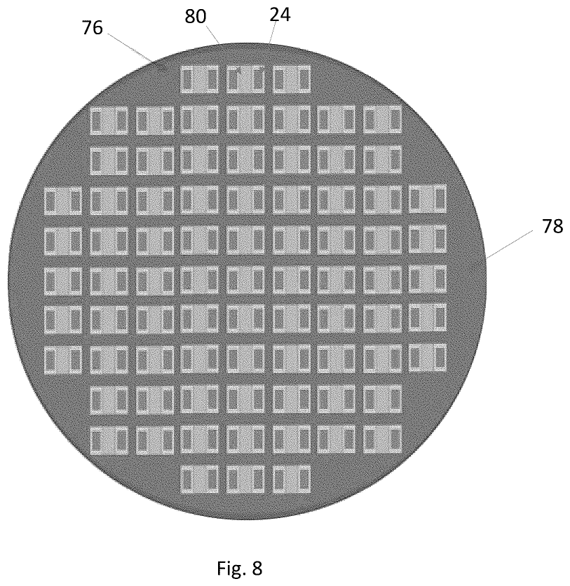

FIG. 8 shows a schematic top plan view of a plurality of frame structures 76 formed in or with a frame substrate 78 (e.g., a wafer, a panel, etc.). The frame structure 76 can comprise any one or more of frame structures disclosed herein. According to some embodiments, a method of forming the frame structures 76 can comprise coating a resist layer over a frame substrate 78 and patterning the resist layer. In some embodiments, the frame substrate 78 can include active components, passive components, optical components, mechanical components, through substrate electrodes, through substrate vias, and/or contact pads (not shown) on one or both surfaces. The method of forming the frame structures 76 can include removing (e.g., etching) portions of the frame substrate 78 to define cavities, such as die cavities 80 and openings 24, and removing (e.g., stripping) the patterned resist layer and other unwanted materials from the frame substrate 78. The method of forming the frame structures 76 can include preparing (e.g., cleaning, polishing, etc.) the frame substrate 78 with the frame structures 76 for bonding. The preparation can include preparing the frame substrate 78 for direct bonding or direct hybrid bonding as disclosed herein. According to some other embodiments, a method of forming the frame structures 76 can comprise laser dicing or water jet dicing portions of the frame substrate 78.

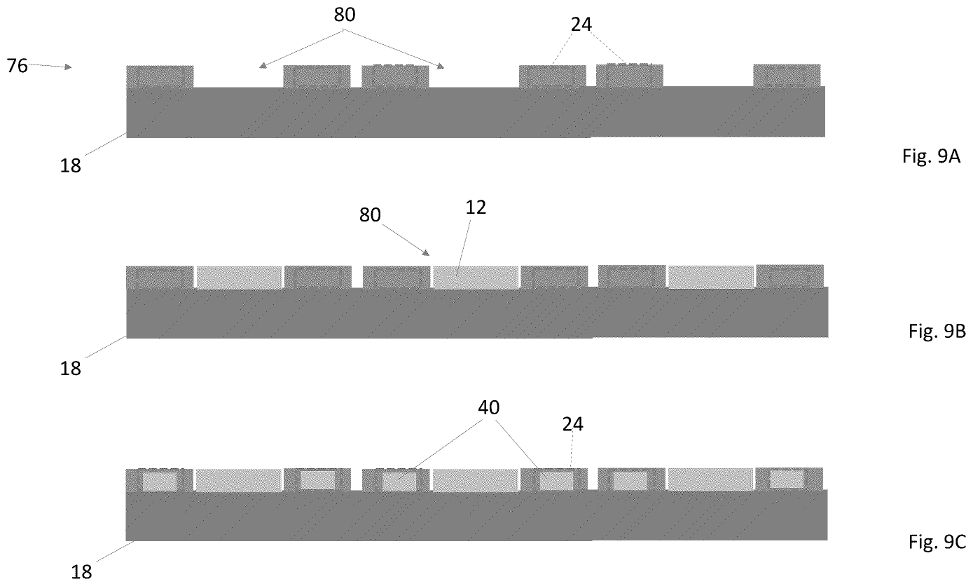

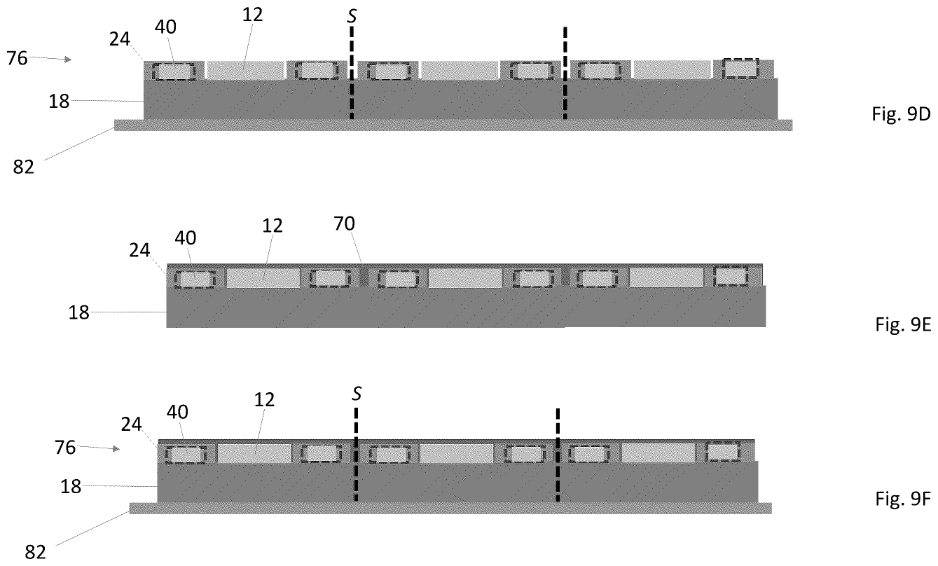

FIGS. 9A-9F show a method of forming a bonded structure according to an embodiment. FIG. 9A is a schematic side view of frame structures 76 on a carrier 18. The frame structures 76 can be bonded (e.g. wafer to wafer bonding via direct bonding) to the carrier 18 directly without an intervening adhesive or by way of an adhesive (not shown). The frame structures 76 can comprise and suitable one or more of the frame structures disclosed herein. The frame structures 76 can comprise die cavities 80 and openings 24.

In FIG. 9B, integrated device dies 12 can be provided in the die cavities. The integrated device dies 12 can be bonded to the carrier 18 by way of any suitable manner disclosed herein. For example, the carrier 18 and the integrated device dies 12 can be prepared for direct bonding, and the integrated device dies 12 can be directly bonded to the carrier 18 without an intervening adhesive. In some embodiments, the carrier 18 can comprise test pads (not show) for testing electrical connections between the integrated device dies 12 and the carrier 18.

In FIG. 9C, electronic components 40 can be provided in the openings 24.

The electronic components 40 can be bonded to the carrier 18 by way of any suitable manner disclosed herein. For example, the carrier 18 and the electronic components 40 can be prepared for direct bonding, and the electronic components 40 can be directly bonded to the carrier 18 without an intervening adhesive. In some embodiments, the carrier 18 can comprise test pads (not show) for testing electrical connections between the electronic components 40 and the carrier 18.

In FIG. 9D, the structure formed in FIG. 9C can be provided on a dicing tape 82, and singulated into a plurality of singulated bonded structures. In some embodiments, singulation can comprise a sawing process, an etching process, or any other suitable process. In some embodiments, a protective coating (not shown) can be provided over the integrated device dies 12 and the electronic components 40 prior to singulation.

In FIG. 9E, the structure formed in FIG. 9C can be encapsulated (e.g., deposited with) a protective material 70. In some embodiments, the protective material 70 can comprise an organic material such as a molding compound or a polymer material (e.g., resin, epoxy or potting compound, etc.), or an inorganic material such as silicon oxide, silicon nitride, etc. The protective material 70 can fill areas of the die cavities 80 and the openings 24 that are not occupied by the integrated device die 12 and the electronic components 40. One or more coatings or layers of one or more protective material can be deposited in the die cavities, the openings and on the top of the dies and the frame structure 76. After the depositing the protective material 70, the stack structure can be polished to thin the frame side of the stacked structure. In some embodiments, RDL and interconnections may be formed on top of the framed structure connecting the integrated device dies 12 and the electronic components 4 etc. As explained herein, in some embodiments, the upper surface of the protective material 70 can be planarized and prepared for bonding. In some embodiments, conductive contact features can be patterned in the protective material 70. Additional devices can be stacked and direct bonded to the upper surface of the protective material 70. In some embodiments, the additional devices can be encapsulated in a protective material.

In FIG. 9F, the structure formed in FIG. 9E can be provided on a dicing tape 82, and singulated into a plurality of singulated bonded structures. In some embodiments, singulation can comprise a sawing process, an etching process, or any other suitable process. In some embodiments, a singulation street S can be located between the frame structures 76. In some embodiments, the singulation street S extends through at least a portion of the frame structures 76.

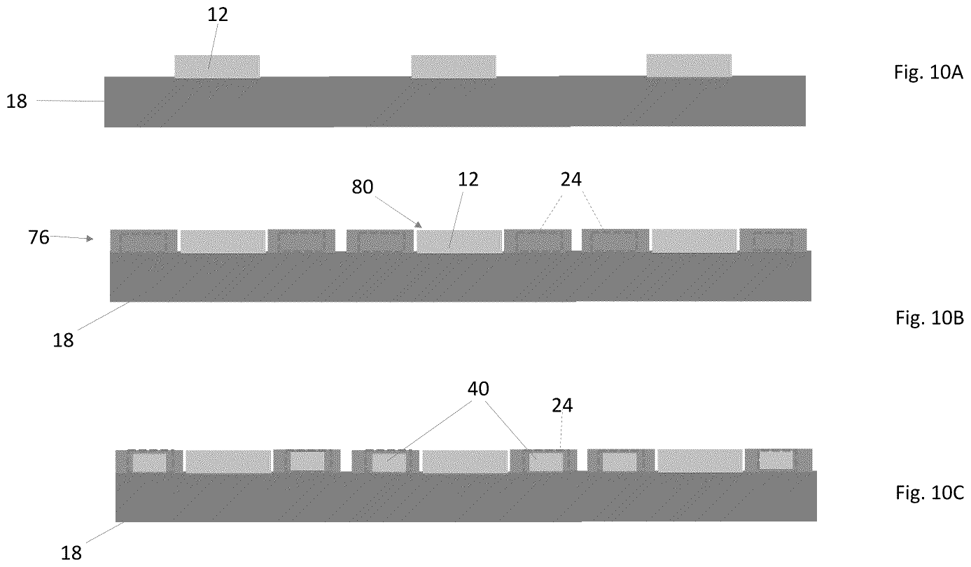

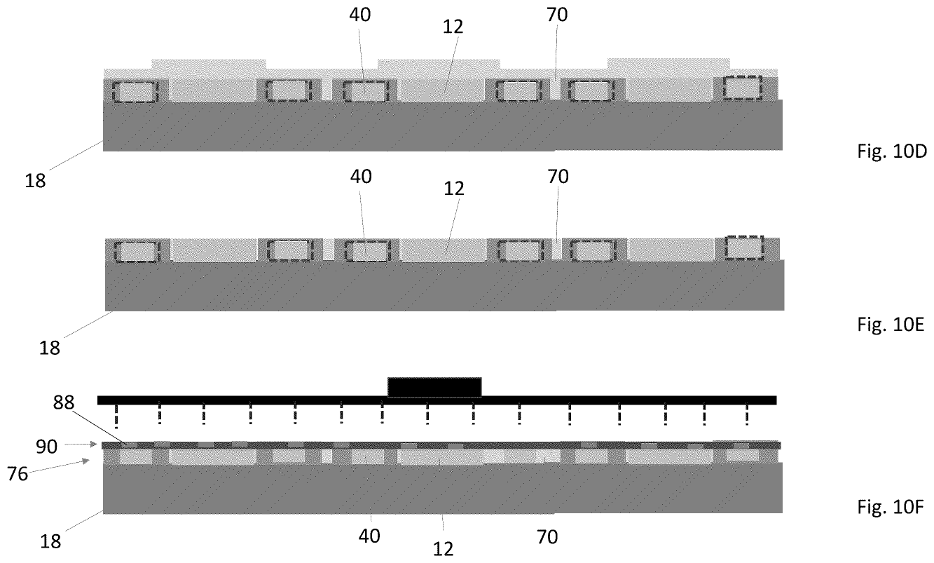

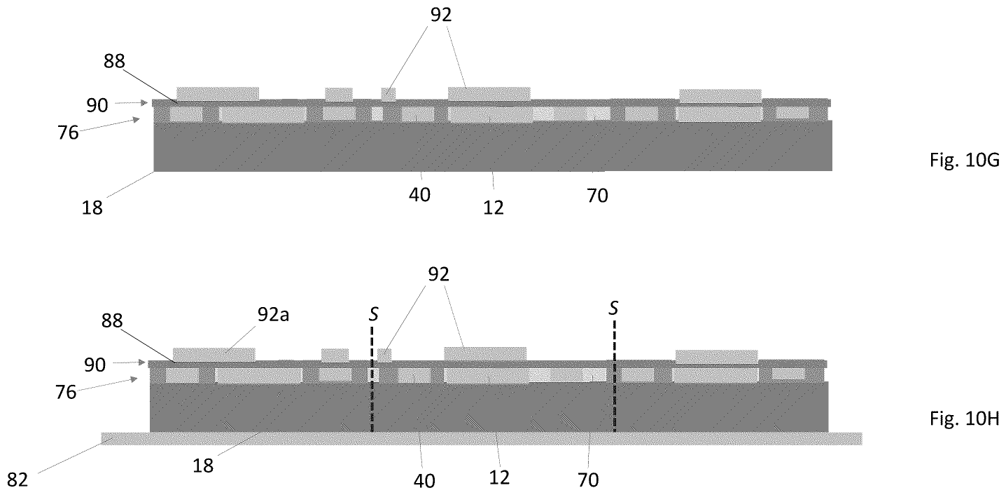

FIGS. 10A-10H show a method of forming a bonded structure according to an embodiment. FIG. 10A is a schematic side view of integrated device dies 12 bonded to a carrier 18. The integrated device dies 12 can be bonded to the carrier 18 by way of any suitable manner disclosed herein. For example, the carrier 18 and the integrated device dies 12 can be prepared for direct bonding, and the integrated device dies 12 can be directly bonded to the carrier 18 without an intervening adhesive. In some embodiments, the carrier 18 can comprise test pads (not show) for testing electrical connections between the integrated device dies 12 and the carrier 18. In alternated embodiments, the frame structure 76 can be bonded to the carrier 18 to stabilize the entire structure before bonding the integrated device dies 12 and any other dies thereof.

In FIG. 10B frame structures 76 can be provided such that the integrated device dies 12 are disposed in the dies cavities 80 of the frame structures 76. The frame structures 76 can be bonded to the carrier 18 directly without an intervening adhesive or by way of an adhesive (not shown). The frame structures 76 can comprise and suitable one or more of the frame structures disclosed herein.

In FIG. 10C, electronic components 40 can be provided in the openings 24. The electronic components 40 can be bonded to the carrier 18 by way of any suitable manner disclosed herein. For example, the carrier 18 and the electronic components 40 can be prepared for direct bonding, and the electronic components 40 can be directly bonded to the carrier 18 without an intervening adhesive. In some embodiments, the carrier 18 can comprise test pads (not show) for testing electrical connections between the electronic components 40 and the carrier 18.

In FIG. 10D, protective material 70 can be provided. In some embodiments, the protective material 70 can comprise an organic material such as a molding compound or a polymer material (e.g., an epoxy or potting compound), or an inorganic material such as silicon oxide, silicon nitride or a combination thereof. The protective material 70 can fill areas of the die cavities 80 and the openings 24 that are not occupied by the integrated device die 12 and the electronic components 40.

In FIG. 10E, portions of the protective material 70 over the integrated device die 12 and the electronic components 40 can be removed. In some embodiments, a planarization process, such as chemical mechanical polishing (CMP) can be used to remove the portions of the protective material over the integrated device die 12 and the electronic components 40.

In FIG. 10F, conductive elements 88 can be formed over a surface of the structure formed in FIG. 10E. In some embodiments, the conductive elements 88 can comprise at least a portion of a redistribution layer (RDL) 90. The conductive elements 88 can be formed on the integrated device dies 12, electronic components 40, and/or the frame structures 76. The conductive elements 88 can be electrically connected to the substrate 18 at least partially through, for example, the vertical interconnects 62 disposed in the frame structure 60a as described with respect to FIG. 7G. In some embodiments, the integrated device die 12 may comprise through substrate electrodes, such as, for example, thru-silicon vias (TSVs) when the substrate of the integrated device die 12 comprise silicon.

In FIG. 10G, additional electronic components 92 can be provided on the RDL 90. For example, the electronic components 92 can comprise a processor die, a memory die, a sensor die, a microelectromechanical systems (MEMS) die, a stack of multiple dies or elements, or any other suitable device that includes active circuitry (such as transistors or other active devices). In some embodiments, the electronic components 92 can comprise power dies configured to supply power to other components of the structure. In some embodiments, the components 92 can additionally or alternatively be wire bonded to 82 (and wire bonds can be encapsulated/molded). The electronic components 92 can be bonded to the RDL 90 in any suitable manner disclosed herein. In some embodiments, the electronic components 92 can be encapsulated with a protective material, which can be prepared for direct bonding (including, e.g., forming conductive contacts in the protective material). Additional components (not shown) can be directly bonded to the protective material (and associated contacts) in which the components 92 are at least partially embedded. The electronic component can be electrically connected to the substrate 18 at least partially through the frame structure 76 (e.g., the vertical interconnects 62 disposed in the frame structure 60a as described with respect to FIG. 7G), through vertical interconnects of the integrated dies 12, or through both the frame structure 76 and the integrated device die 12. The electronic components 92 can include an electronic component 92a. In some embodiments, the electronic component 92a can comprise a bridge component in which portions of the electronic component 92a overlap a portion of the frame structure 76 and a portion of the integrated device die 12. The bridge component or die can be electrically connected to the substrate 18 through the frame structure 76 and also through the integrated device die 12.

In FIG. 10H, the structure formed in FIG. 10G can be provided on a dicing tape 82, and singulated into a plurality of singulated bonded structures. In some embodiments, singulation can comprise a sawing process, an etching process, or any other suitable process. In some embodiments, a singulation street S can be located between the frame structures 76. In some embodiments, the singulation street S extends through at least a portion of the frame structures 76.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. It is also contemplated that various combinations or sub-combinations of the specific features and aspects of the embodiments may be made and still fall within the scope. The accompanying claims and their equivalents are intended to cover such forms or modifications as would fall within the scope and spirit of the disclosure.

What is claimed is:

1. A bonded structure comprising:
a carrier including a surface having a first region and a second region;
an integrated device die directly bonded to the first region of the carrier; and
a continuous frame structure on the second region, the continuous frame structure having a first section extending in a first direction and a second section extending in a second direction angled relative to the first direction, the first and second sections disposed at least partially around a portion of the second region, the portion of the second region disposed between the second section and the integrated device die.

2. The bonded structure of claim 1, wherein at least the portion of the second region between the integrated device die and the second section is free from the continuous frame structure.

3. The bonded structure of claim 1, wherein a nonconductive field region of the integrated device die is directly bonded to a nonconductive field region of the carrier, and a conductive feature of the integrated device die is directly bonded to a conductive feature of the carrier.

4. The bonded structure of claim 1, wherein the continuous frame structure is directly bonded to the carrier.

5. The bonded structure of claim 1, wherein the continuous frame structure further includes a third section extending in a third direction angled relative to the second direction and a fourth section extending in a fourth direction angled relative to the third direction, the first to forth sections defining an annular frame.

6. The bonded structure of claim 1, wherein a width of the first section is greater than a width of the second section.

7. The bonded structure of claim 1, wherein the first section has varying widths along its width.

8. The bonded structure of claim 1, wherein 80% or less of the second region is free from the continuous frame structure.

9. The bonded structure of claim 1, further comprising a second frame structure on a third region of the carrier, the first region positioned between the second region and the third region.

10. The bonded structure of claim 9, wherein the second frame structure comprises a second continuous frame structure that includes a first section angled relative to a second section.

11. The bonded structure of claim 9, wherein the second frame structure comprises a first frame element and a second frame element that is spaced from the first frame element.

12. The bonded structure of claim 1, wherein the continuous frame structure comprises a via that extends through a thickness of the continuous frame structure.

13. The bonded structure of claim 12, further comprising an element stacked on the continuous frame structure.

14. The bonded structure of claim 1, wherein the continuous frame structure comprises no active circuitry.

15. The bonded structure of claim 1, wherein the continuous frame structure comprises a passive element.

16. The bonded structure of claim 1, further comprising a protective material disposed at least partially between the integrated device die and the continuous frame structure.

17. The bonded structure of claim 16, wherein the protective material comprises a molding compound.

18. The bonded structure of claim 1, further comprising electronic components disposed in the second region between the integrated device die and the second section of the continuous frame structure.

19. A bonded structure comprising:
a carrier including a surface having a first region and a second region;
an integrated device die directly bonded to the first region of the carrier; and
a frame structure on the second region, the frame structure having a first elongate frame element and a second elongate frame element positioned between the integrated device die and the second region, at least a portion of the second region between the first frame element and the second frame element being free from the frame structure.

20. The bonded structure of claim 19, wherein a nonconductive field region of the integrated device die is directly bonded to a nonconductive field region of the carrier, and a conductive feature of the integrated device die is directly bonded to a conductive feature of the carrier.

21. The bonded structure of claim 19, wherein the frame structure is directly bonded to the carrier.

22. The bonded structure of claim 19, the frame structure further includes a third frame element, wherein the first frame element extends in a first direction, the second frame element extends in a second direction, and the third frame element extends in a third direction that is angled relative to the first and second directions.

23. The bonded structure of claim 22, the frame structure further includes a fourth frame element that extends in a fourth direction angled relative to the first and second directions.

24. The bonded structure of claim 19, wherein the frame structure comprises no active circuitry.

25. The bonded structure of claim 19, wherein the frame structure comprises a passive element.

26. The bonded structure of claim 19, further comprising a molding compound disposed at least partially between the integrated device die and the frame structure.

27. The bonded structure of claim 19, further comprising electronic components disposed in the second region between the first and second frame elements.

28. A bonded structure comprising:
a carrier including a surface having a first region and a second region;
an integrated device die directly bonded to the first region of the carrier; and
a frame structure disposed on the second region, the frame structure having a through via extending through a thickness of the frame structure, the frame structure having no active circuitry therein.

29. The bonded structure of claim 28, wherein the frame structure comprises a continuous frame structure having a first section extending in a first direction and a second section extending in a second direction angled relative to the first direction, at least a portion of the second region between the integrated device die and the second section of the continuous frame structure being free from the continuous frame structure.

30. The bonded structure of claim 28, wherein the frame structure has a first elongate frame element and a second elongate frame element positioned between the integrated device die and the second region, at least a portion of the second region between the first frame element and the second frame element being free from the frame structure.
